(19) United States
(12) Patent Application Publication
(10) Pub. No.: US 2025/0311153 A1
(43) Pub. Date: Oct. 2, 2025

(54) IMMERSION COOLING TANK AND IMMERSION COOLING SYSTEM INCLUDING THE SAME

(71) Applicant: Delta Electronics, Inc., Taoyuan City (TW)

(72) Inventors: Yi-Tseng LI, Taoyuan City (TW); Shih-Kang LIN, Taoyuan City (TW); Chao-Wen LU, Taoyuan City (TW); Li-Kuang TAN, Taoyuan City (TW)

(21) Appl. No.: 18/828,058

(22) Filed: Sep. 9, 2024

(30) Foreign Application Priority Data
Mar. 29, 2024 (CN) 202420642757.X

(51) Int. Cl. H05K 7/20

(52) U.S. Cl. CPC H05K 7/20272; H05K 7/20236; H05K 7/20263

(57) ABSTRACT

An immersion cooling tank is provided. The immersion cooling tank includes a casing and a piping assembly. The casing includes a positioning element defining the lowest installation surface of an electronic device. The piping assembly includes an inflow branch pipe and a plurality of flow inlets. The flow inlets correspond to the lowest installation surface of the electronic device. The flow inlets are provided on the inflow branch pipe. The size of each of the flow inlets is 1/4.5 to 1/6.5 of the size of the inflow branch pipe.

### CROSS REFERENCE TO RELATED APPLICATIONS

This application claims priority of China Utility Model Application No. 202420642757.X, filed on Mar. 29, 2024, the entirety of which is incorporated by reference herein.

### BACKGROUND OF THE INVENTION

### Field of the Invention

The present disclosure relates to an immersion cooling tank and an immersion cooling system including the same.

### Description of the Related Art

Immersion cooling systems using fluid to cool electronic devices are flourishing. However, current immersion cooling systems are not satisfactory in all respects.

### BRIEF SUMMARY OF THE INVENTION

Some embodiments of the present disclosure provide an immersion cooling tank. The immersion cooling tank includes a casing and a piping assembly. The casing includes a positioning element defining the lowest installation surface of an electronic device. The piping assembly includes an inflow branch pipe and a plurality of flow inlets. The flow inlets correspond to the lowest installation surface of the electronic device. The flow inlets are provided on the inflow branch pipe. The size of each of the flow inlets is 1/4.5 to 1/6.5 of the size of the inflow branch pipe.

In some embodiments, the minimum distance between the lowest installation surface and corresponding one of the flow inlets is between 1 mm and 30 mm. In some embodiments, the immersion cooling tank further includes a fluid entrance and an inflow main pipe in fluid communication with the fluid entrance. The inflow branch pipe is in fluid communication with the inflow main pipe. The size of the inflow branch pipe is different from the size of the inflow main pipe. In some embodiments, the size of inflow branch pipe is less than the size of the inflow main pipe.

In some embodiments, the piping assembly further includes a fluid exit, an outlet pipe, and a flow outlet. The outlet pipe is in fluid communication with the fluid exit. The flow outlet is in fluid communication with the outlet pipe. The fluid exit is located over the fluid entrance. In some embodiments, the size of each of the flow inlets is less than the size of the flow outlet. In some embodiments, the size of the outlet pipe is equal to size of the flow outlet.

In some embodiments, the fluid enters the immersion cooling tank through the fluid entrance, sequentially flows through the inflow main pipe, the inflow branch pipe, and the flow inlets to cool the electronic device. In some embodiments, after heat generated by the electronic device is absorbed by the fluid, the fluid sequentially flows through the flow outlet and the outlet pipe and exits the immersion cooling tank through the fluid exit.

In some embodiments, the electronic device corresponds to two rows of flow inlets. In some embodiments, the immersion cooling tank further includes a ring-shaped divider element disposed on an inner wall surface of the casing. In some embodiments, the immersion cooling tank further includes a base provided below the ring-shaped divider element.

Some embodiments of the present disclosure provide an immersion cooling tank. The immersion cooling tank includes a casing and a piping assembly. The piping assembly includes a fluid entrance, a fluid exit, and a ring-shaped divider element. The fluid entrance is provided on the casing. A fluid enters the casing through the fluid entrance. The fluid exit is provided on the casing. The fluid exits the casing through the fluid exit. The ring-shaped divider element is disposed on the inner wall surface of the casing, and the ring-shaped divider element protrudes from the inner wall surface of the casing. The ring-shaped divider element is located between the fluid entrance and the fluid exit, so the interior of the casing is divided into a first zone and a second zone located over the first zone.

In some embodiments, the temperature of the fluid in the first zone is different from the temperature of the fluid in the second zone. In some embodiments, the temperature of the fluid in the first zone is less than the temperature of the fluid in the second zone. In some embodiments, the immersion cooling tank further includes a baffle, and the ring-shaped divider element surrounds the baffle. In some embodiments, the ring-shaped divider element and the casing are in a close fit. In some embodiments, the first zone is the area surrounded by the ring-shaped divider element. In some embodiments, the second zone is the area located over a topmost surface of the ring-shaped divider element.

Some embodiments of the present disclosure provide an immersion cooling system including the aforementioned immersion cooling tank, a heat exchanger, and a pump. The fluid entering and exiting the immersion cooling tank is extracted to the heat exchanger by the pump.

### BRIEF DESCRIPTION OF THE DRAWINGS

The present disclosure can be more fully understood by reading the detailed description and examples with references made to the accompanying drawings. It should be noted that various features may be not drawn to scale. In fact, the dimensions of the various features may be arbitrarily increased or decreased for clarity of discussion, and the various features may be drawn schematically.

FIG. 1 is a perspective view of the immersion cooling system, in accordance with some embodiments.

FIG. 2 and FIG. 3 are perspective views of the immersion cooling tank from different perspectives, in accordance with some embodiments.

FIG. 4 is an enlarged side view of part of the immersion cooling tank, in accordance with some embodiments.

FIG. 5 and FIG. 6 are perspective views of the immersion cooling tank from different perspectives, in accordance with some embodiments.

FIG. 7 is an enlarged perspective view of part of the immersion cooling tank, in accordance with some embodiments.

FIG. 8 is an enlarged side view of part of the immersion cooling tank, in accordance with some embodiments.

FIG. 9 and FIG. 10 are perspective views of the immersion cooling tank from different perspectives, in accordance with some embodiments.

FIG. 11 is a perspective view of the piping assembly, in accordance with some embodiments.

FIG. 12 is a top view of the piping assembly, in accordance with some embodiments.

FIG. 13A and FIG. 13B illustrate the positional relationship between the flow inlets and the electronic device, in accordance with some embodiments.

### DETAILED DESCRIPTION OF THE INVENTION

The following description provides different embodiments, or examples, for implementing different features of the present disclosure. For example, the formation of a first feature “on” or “over” a second feature in the following description may include embodiments in which the first and second features are formed in direct contact, and may also include embodiments in which additional features may be formed between the first feature and the second feature, such that the first feature and the second feature are not in direct contact. These spatially relative terms are intended to encompass different orientations of the device in use or operation in addition to the orientation illustrated in the drawings. The device may be otherwise oriented (rotated 90 degrees or at other orientations), and the spatially relative terms used in the following description may likewise be interpreted accordingly.

Ordinal terms such as “first”, “second”, etc., used in the description and claims do not by themselves connote any priority, precedence, or order of one feature over another, but are used merely as labels to distinguish one feature from another feature having the same name. Therefore, a first feature in the description may be referred to as a second feature in claims. In addition, the terms “including”, “comprising”, “having”, and the like should be interpreted as meaning “including but not limited to . . . ”. Therefore, when the terms “including”, “comprising”, “having”, and the like are used, the presence of corresponding features, regions, steps, operations and/or elements is specified, and without excluding the presence of other features, regions, steps, operations and/or elements.

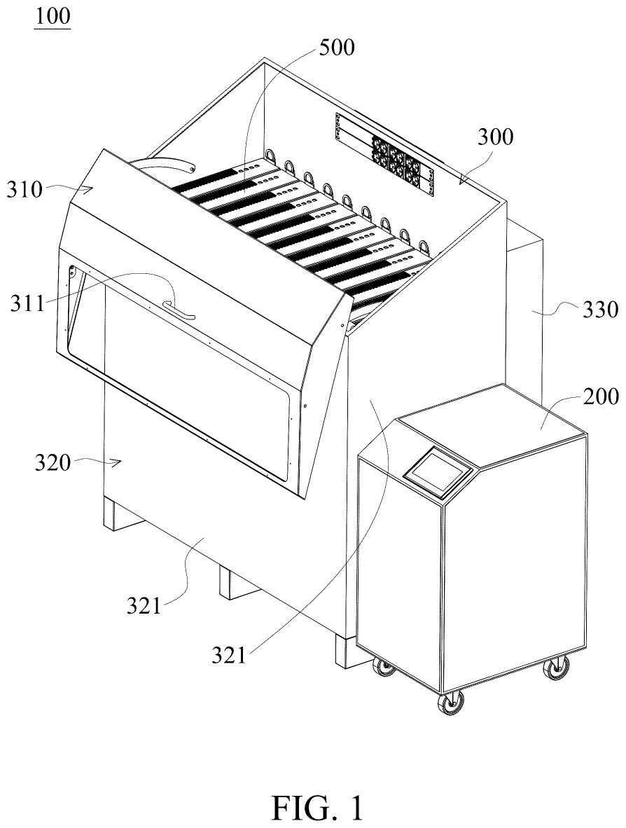

Please refer to FIG. 1 to understand an immersion cooling system 100. FIG. 1 is a perspective view of the immersion cooling system 100, in accordance with some embodiments. The immersion cooling system 100 may be used to cool a plurality of electronic devices 500. The electronic devices 500 may be traditional servers, artificial intelligence (AI) servers, devices including a backup battery unit (BBU), etc., but the types of the electronic devices are not limited thereto.

The immersion cooling system 100 includes a pump (not shown), a heat exchanger 200, and an immersion cooling tank 300. The electronic devices 500 can be immersed in a fluid (which can be single-phase or two-phase) in the immersion cooling tank 300 and thereby be cooled. The fluid entering and exiting the immersion cooling tank 300 can be extracted to the heat exchanger 200 by the pump to adjust the temperature of the fluid. For example, the heat exchanger 200 can ensure that the fluid is sufficiently cold (for cooling the electronic devices 500) before entering the immersion cooling tank 300. In some embodiments, the heat exchanger 200 may possess a control function and thus act as a control device.

The immersion cooling tank 300 may include an upper casing 310, a front casing 320, and a rear casing 330. In some embodiments, the upper casing 310, the front casing 320, and the rear casing 330 may be collectively referred to as a casing. The upper casing 310 is disposed on the front casing 320, and the upper casing 310 is connected to the front casing 320. In some embodiments, the upper casing 310 includes a handle 311. In some embodiments, the upper casing 310 can be moved by holding the handle 311 to place in or take out the electronic devices 500.

In some embodiments, the front casing 320 includes a plurality of walls 321. The walls 321 surround the electronic devices 500. In some embodiments, the walls 321 include metal, for example, a highly thermally conductive metal, but the material of the walls 321 is not limited thereto. The rear casing 330 is disposed behind the front casing 320. In some embodiments, the rear casing 330 includes the same material as the front casing 320, but the material of the rear casing 330 is not limited thereto.

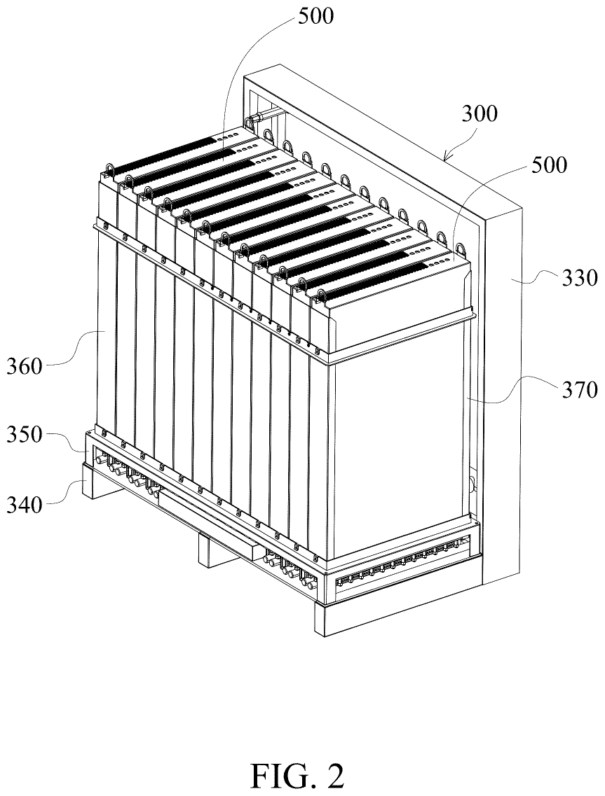

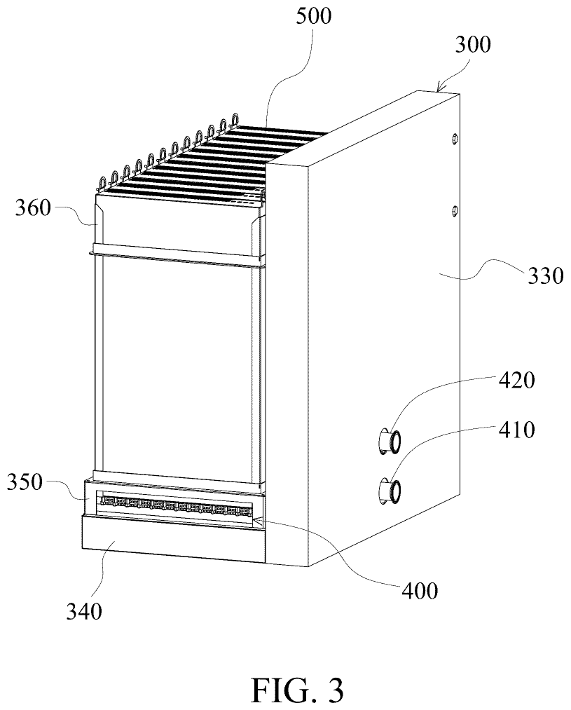

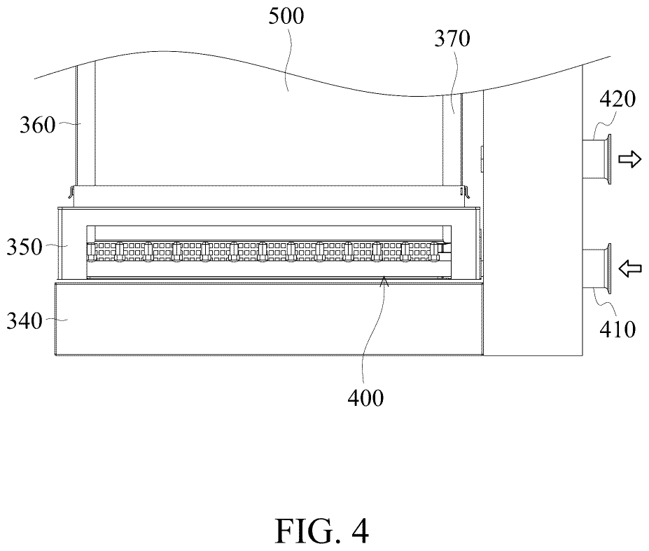

Next, please refer to FIG. 2 to FIG. 8 to know more about the immersion cooling tank 300. For ease of illustration, the upper casing 310 and the front casing 320 are omitted in FIG. 2 to FIG. 4. FIG. 2 and FIG. 3 are perspective views of the immersion cooling tank 300 from different perspectives, in accordance with some embodiments. FIG. 4 is an enlarged side view of part of the immersion cooling tank 300, in accordance with some embodiments.

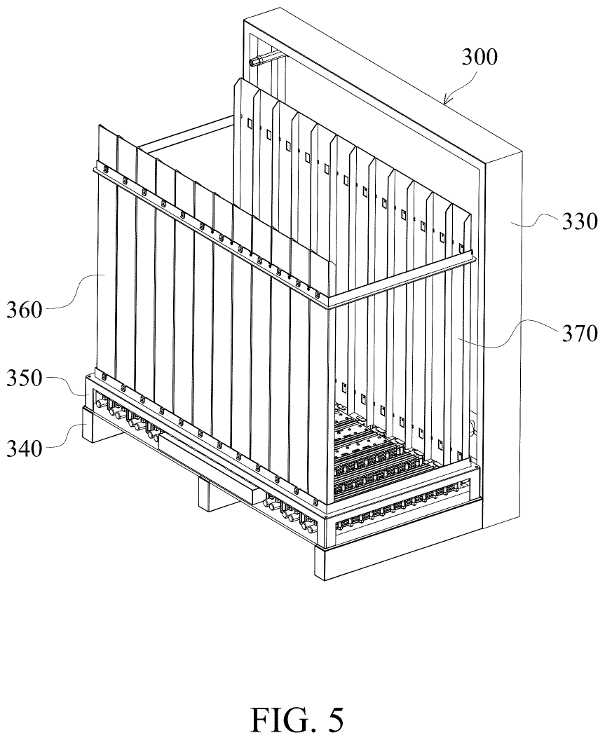

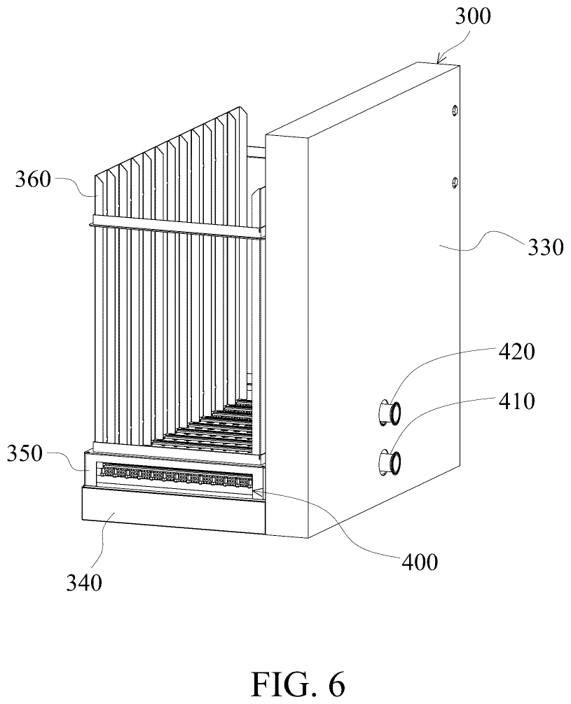

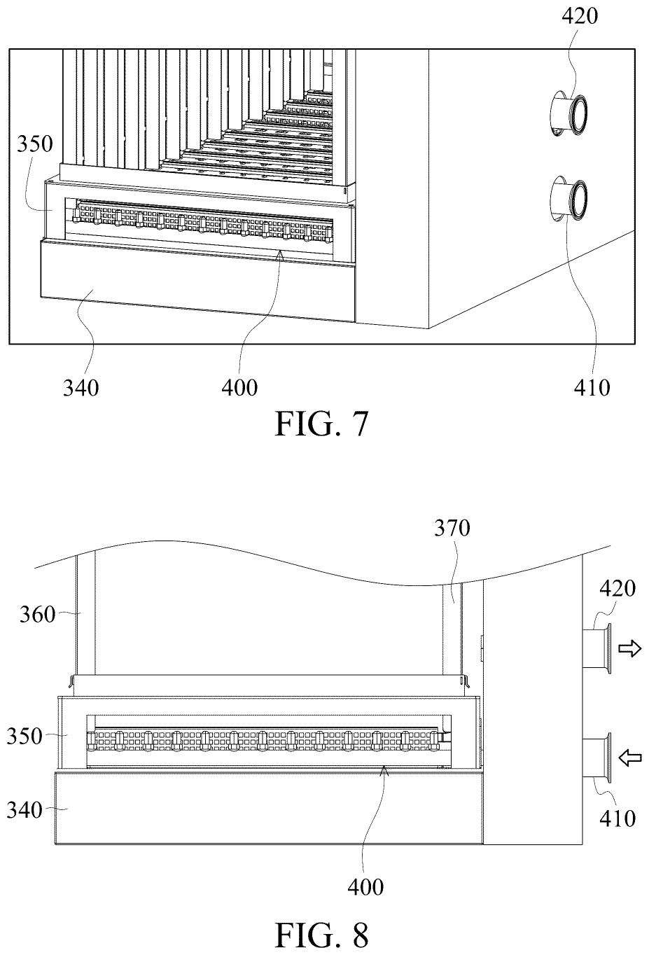

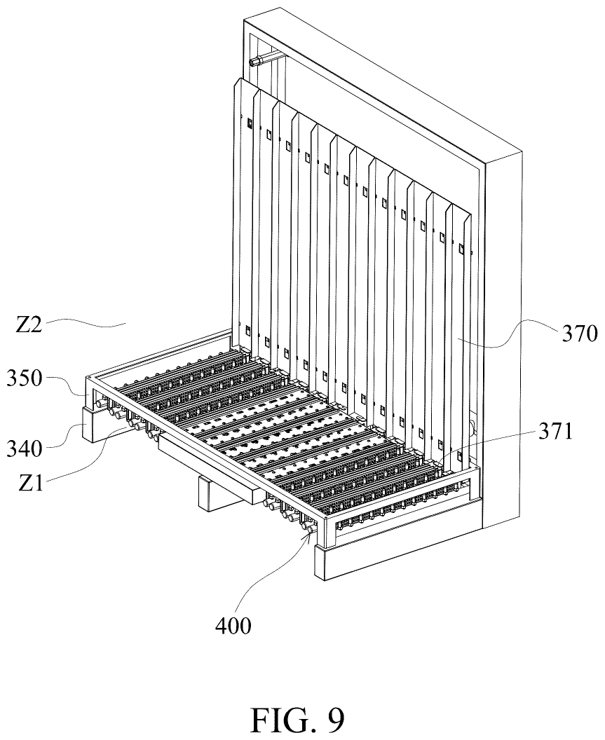

In addition, for ease of illustration, the electronic devices 500 are omitted in FIG. 5 to FIG. 8. FIG. 5 and FIG. 6 are perspective views of the immersion cooling tank 300 from different perspectives, in accordance with some embodiments. FIG. 7 is an enlarged perspective view of part of the immersion cooling tank 300, in accordance with some embodiments. FIG. 8 is an enlarged side view of part of the immersion cooling tank 300, in accordance with some embodiments.

The immersion cooling tank 300 may further include a base 340, a ring-shaped divider element 350, a plurality of front baffles 360, a plurality of rear baffles 370, and a piping assembly 400.

The base 340 is provided below the ring-shaped divider element 350. The base 340 may possess a supporting function. In some embodiments, the base 340 includes a plurality of cuboids.

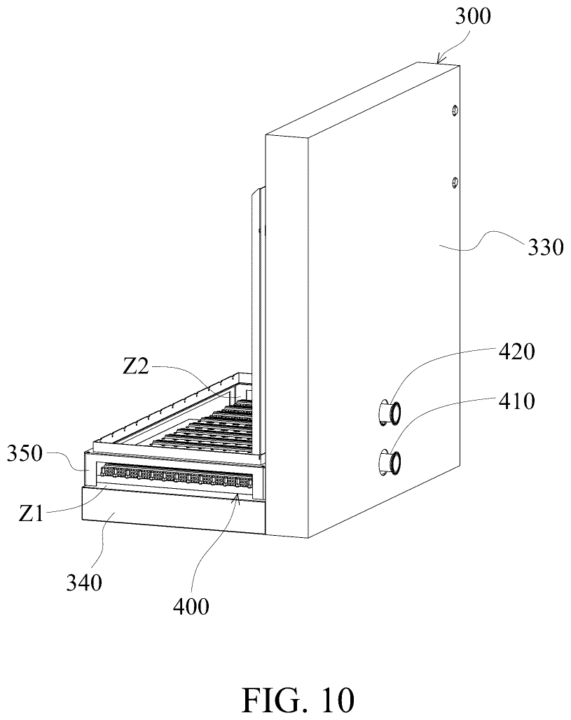

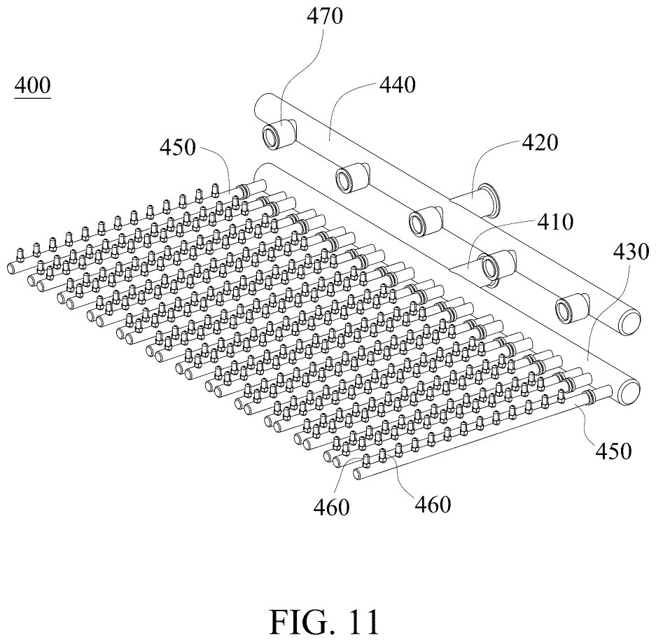

The ring-shaped divider element 350 is disposed on the inner wall surface of the front casing 320 in a protruding way. That is, the ring-shaped divider element 350 is disposed on the inner wall surface of the front casing 320, and the ring-shaped divider element 350 protrudes from the inner wall surface of the front casing 320. In some embodiments, the ring-shaped divider element 350 and the front casing 320 are in a close fit. That is, the ring-shaped divider element 350 and the front casing 320 are snugly arranged with nearly no space between them. In some embodiments, the ring-shaped divider element 350 can surround the front baffles 360 and the rear baffles 370 and thus affix the front baffle 360 and the rear baffle 370. Details about the ring-shaped divider element 350 will be described in detail below with reference made to FIG. 9 and FIG. 10.

The front baffles 360 and the rear baffles 370 are used to affix and separate the electronic devices 500. In some embodiments, a pair of one front baffle 360 and one rear baffle 370 are used to secure one electronic device 500. Through the front baffles 360 and the rear baffles 370, the electronic devices 500 can be arranged in a relatively close way, which can improve the space utilization within the interior of the immersion cooling tank 300.

In some embodiments, the front baffles 360 and the rear baffles 370 may respectively include a front positioning element (not shown) and a rear positioning element 371 (denoted in FIG. 9) to define the lowest installation surface of each of the electronic devices 500 and reduce the possibility that the electronic device 500 collides with the piping assembly 400. In some embodiments, both the front positioning element and the rear positioning element 371 can be protrusions, and the protrusions are parallel with the lowest installation surface of the electronic devices 500, but the structures of the front positioning element and the rear positioning element 371 are not limited thereto.

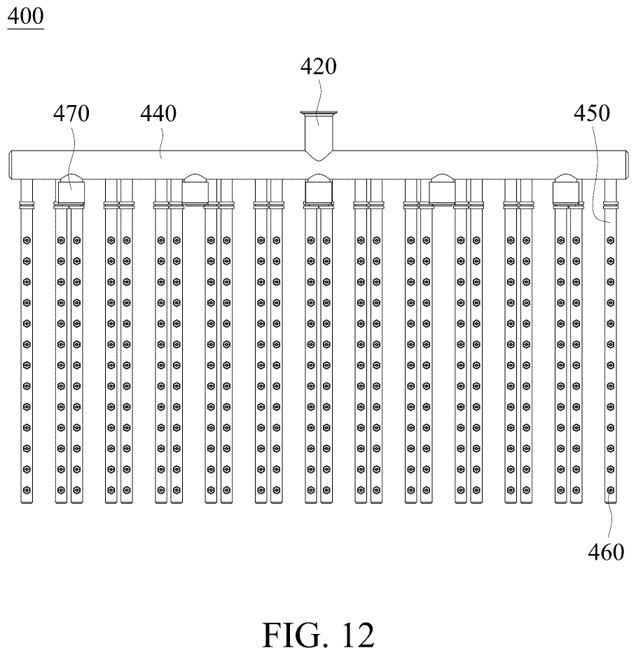

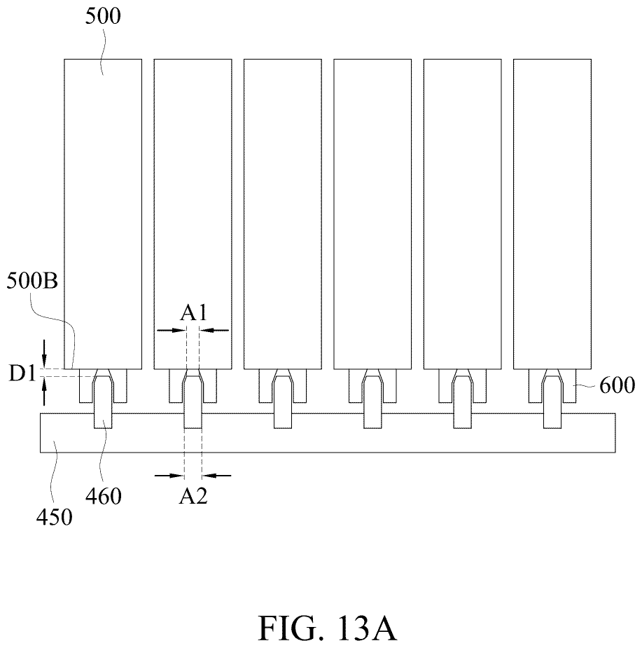

The piping assembly 400 includes a fluid entrance 410 and a fluid exit 420. In some embodiments, the fluid entrance 410 and the fluid exit 420 are provided on the rear casing 330, and the fluid exit 420 is located over the fluid entrance 410. In FIG. 4 and FIG. 8, the inflow and outflow of the fluid are indicated by arrows. Specifically, the fluid used to cool the electronic devices 500 flows into the immersion cooling tank 300 (e.g., entering the front casing 320) through the fluid entrance 410, and the fluid that has absorbed the heat generated by the electronic devices 500 flows out of the immersion cooling tank 300 (e.g., exiting the front casing 320) through the fluid exit 420. Details about the piping assembly 400 will be described in detail below with reference made to FIG. 11 and FIG. 12.

Next, in addition to FIG. 2 to FIG. 8, please refer to FIG. 9 and FIG. 10 to understand the ring-shaped divider element 350. FIG. 9 and FIG. 10 are perspective views of the immersion cooling tank 300 from different perspectives, in accordance with some embodiments. The ring-shaped divider element 350 is located between the fluid entrance 410 and the fluid exit 420. In some embodiments, the topmost surface of the ring-shaped divider element 350 is located between the fluid entrance 410 and the fluid exit 420 in the vertical direction.

When the fluid for cooling the electronic devices 500 flows into the immersion cooling tank 300 through the fluid entrance 410, the ring-shaped divider element 350 can divide the interior of the immersion cooling tank 300 into a first zone Z1 and a second zone Z2. The second zone Z2 is located over the first zone Z1, in which the temperature of the fluid in the first zone Z1 is different from the temperature of the fluid in the second zone Z2. In some embodiments, the temperature of the fluid in the first zone Z1 is lower than the temperature of the fluid in the second zone Z2.

In some embodiments, the first zone Z1 represents the area where the fluid has not absorbed heat generated by the electronic devices 500, while the second zone Z2 represents the area where the fluid has absorbed heat generated by the electronic devices 500. In some embodiments, the first zone Z1 is the area surrounded by the ring-shaped divider element 350, the second zone Z2 is the area over the topmost surface of the ring-shaped divider element 350, but the difference between the first zone Z1 and the second zone Z2 is not limited thereto.

The ring-shaped divider element 350 can reduce the possibility that the fluid entering the immersion cooling tank 300 through the fluid entrance 410 will flow directly out of the immersion cooling tank 300 through the fluid exit 420 without passing through the electronic devices 500 (i.e., without cooling the electronic devices 500). Alternatively, the ring-shaped divider element 350 serves to mitigate the likelihood of fluid, which has absorbed heat generated by the electronic devices 500, flowing towards the vicinity of the fluid entrance 410. That is, the ring-shaped divider element 350 can effectively segregate fluids of different temperatures, guide the fluid to flow in a desired flow direction, and enhance fluid circulation within the immersion cooling tank 300, thereby improving cooling efficiency.

Next, please refer to FIG. 11 and FIG. 12 to understand the piping assembly 400. FIG. 11 is a perspective view of the piping assembly 400, in accordance with some embodiments. FIG. 12 is a top view of the piping assembly 400, in accordance with some embodiments. In addition to the fluid entrance 410 and the fluid exit 420, the piping assembly 400 may include an inflow main pipe 430, an outlet pipe 440, a plurality of inflow branch pipes 450, a plurality of flow inlets 460, and a plurality of flow outlets 470.

The inflow main pipe 430 is in fluid communication with the fluid entrance 410. The inflow branch pipes 450 are in fluid communication with the inflow main pipe 430. The flow inlets 460 are in fluid communication with the inflow branch pipes 450. That is, the fluid sequentially flows through the fluid entrance 410, the inflow main pipe 430, the inflow branch pipes 450, and the flow inlets 460 and flows into the immersion cooling tank 300 to cool the electronic devices 500. In some embodiments, each of the electronic devices 500 corresponds to two rows of flow inlets 460, but the arrangement of the flow inlets 460 is not limited thereto. Compared with the circumstances where each of the electronic devices 500 corresponds to only one row of flow inlets 460, the arrangement where each of the electronic devices 500 corresponds to two rows of flow inlets 460 can improve cooling effects.

In some embodiments, the size of the inflow main pipe 430, the size of each of the inflow branch pipes 450, and the size of the flow inlets 460 are different from each other. In some embodiments, the size of each of the flow inlets 460 is 1/4.5 to 1/6.5 of the size of each of the inflow branch pipes 450. In other words, the size of each of the inflow branch pipes 450 is 4.5 times to 6.5 times the size of each of the flow inlets 460, and the expression “1/4.5 to 1/6.5” is based on the size of each of the flow inlets 460, with the numerator expressed as 1. Through the design of the size of each of the flow inlets 460, the fluid in the inflow branch pipes 450 can flow out from each of the flow inlets 460 evenly, and each of the electronic devices 500 can obtain similar cooling effects. That is, the fluid in different flow inlets 460 may have substantially the same amount of flow, flow rate, etc.

The outlet pipe 440 is in fluid communication with the fluid exit 420. The flow outlets 470 are in fluid communication with the outlet pipe 440. That is, the fluid sequentially flows through the flow outlets 470 and the outlet pipe 440 and flows out of the immersion cooling tank 300 through the fluid exit 420. In some embodiments, the size of each of the flow outlets 470 is substantially the same as the size of the outlet pipe 440, but the relationship between their sizes is not limited thereto. In some embodiments, each of the flow outlets 470 has substantially the same size. In some embodiments, the number of flow outlets 470 is much less than the number of flow inlets 460. In some embodiments, the size of each of the inflow branch pipes 450 is less than the size of each of the flow outlets 470.

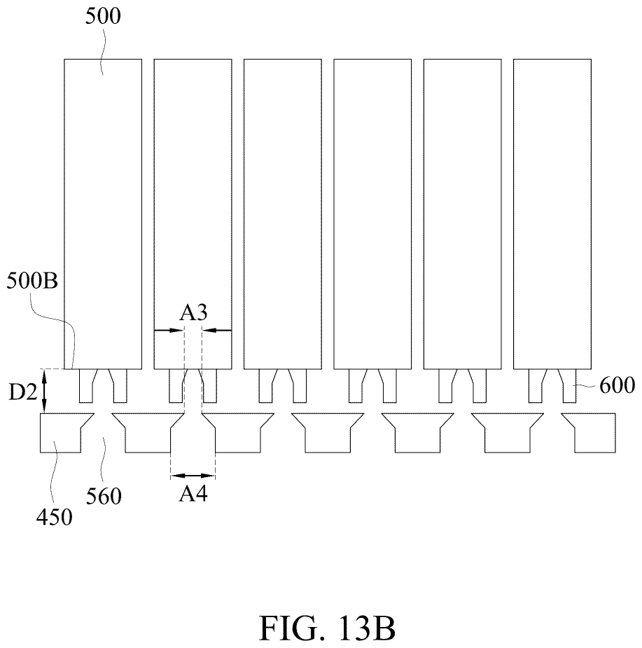

Next, please refer to FIG. 13A and FIG. 13B. FIG. 13A and FIG. 13B illustrate the positional relationship between the flow inlets 460 and the electronic devices 500, in accordance with some embodiments. For ease of illustration, the same or similar elements are denoted by the same or similar reference numerals.

In the embodiments shown in FIG. 13A, the flow inlets 460 protrude relative to the top surface of each of the inflow branch pipes 450. Each of the flow inlets 460 correspond to the lowest installation surface 500B of each of the electronic devices 500 (e.g., the lowest installation surface 500B may be defined by the aforementioned front positioning element and the aforementioned rear positioning element 371). In some embodiments, the minimum distance D1 between the lowest installation surface 500B of the electronic device 500 and the flow inlets 460 is between 1 mm and 30 mm.

Each of the flow inlets 460 may include an inconsistent cross-sectional-area portion. The cross-sectional area of the inconsistent cross-sectional-area portion is inconsistent. The inconsistent cross-sectional-area portion may include a first cross-sectional area A1 and a second cross-sectional area A2, and the first cross-sectional area A1 is different from the second cross-sectional area A2. In some embodiments, the first cross-sectional area A1 is the minimum cross-sectional area of the inconsistent cross-sectional-area portion, and the second cross-sectional area A2 is the maximum cross-sectional area of the inconsistent cross-sectional-area portion. In some embodiments, the ratio of the first cross-sectional area A1 to the second cross-sectional area A2 is between 1/2 and 1/3. In this way, the fluid in the inflow branch pipes 450 can flow out from each of the flow inlets 460 evenly, and each of the electronic devices 500 can obtain similar cooling effects.

In addition, the flow inlets 460 may also include a consistent cross-sectional-area portion connected to the inconsistent cross-sectional-area portion. The consistent cross-sectional-area portion has a consistent cross-sectional area. The inconsistent cross-sectional-area portion is located above the consistent cross-sectional-area portion. In some embodiments, the ratio of the minimum size of the inconsistent cross-sectional-area portion to the size of the cross-sectional area consistent portion is between 1/2 and 1/3. In this way, the fluid in the inflow branch pipes 450 can flow out from each of the flow inlets 460 evenly, and each of the electronic devices 500 can obtain similar cooling effects.

In the embodiments shown in FIG. 13B, the flow inlets 560 are recessed below the top surface of each of the inflow branch pipes 450. Each of the flow inlets 560 correspond to the lowest installation surface 500B of each of the electronic devices 500 (e.g., the lowest installation surface 500B may be defined by the aforementioned front positioning element and the aforementioned rear positioning element 371). In some embodiments, the minimum distance D2 between the lowest installation surface 500B of the electronic device 500 and the flow inlets 560 is between 1 mm and 30 mm.

Each of the flow inlets 560 may include an inconsistent cross-sectional-area portion. The cross-sectional area of the inconsistent cross-sectional-area portion is inconsistent. The inconsistent cross-sectional-area portion may include a first cross-sectional area A3 and a second cross-sectional area A4, and the first cross-sectional area A3 is different from the second cross-sectional area A4. In some embodiments, the first cross-sectional area A3 is the minimum cross-sectional area of the inconsistent cross-sectional-area portion, and the second cross-sectional area A4 is the maximum cross-sectional area of the inconsistent cross-sectional-area portion. In some embodiments, the ratio of the first cross-sectional area A3 to the second cross-sectional area A4 is between 1/2 and 1/3. In this way, the fluid in the inflow branch pipes 450 can flow out from each of the flow inlets 560 evenly, and each of the electronic devices 500 can obtain similar cooling effects.

In addition, the flow inlets 560 may also include a consistent cross-sectional-area portion connected to the inconsistent cross-sectional-area portion. The consistent cross-sectional-area portion has a consistent cross-sectional area. The inconsistent cross-sectional-area portion is located above the consistent cross-sectional-area portion. In some embodiments, the ratio of the minimum size of the inconsistent cross-sectional-area portion to the size of the cross-sectional area consistent portion is between 1/2 and 1/3. In this way, the fluid in the inflow branch pipes 450 can flow out from each of the flow inlets 560 evenly, and each of the electronic devices 500 can obtain similar cooling effects.

Since the minimum distance D1 (or the minimum distance D2) between the lowest installation surface 500B of the electronic device 500 and the flow inlets 460 (or the flow inlets 560) is between 1 mm and 30 mm, almost all the fluid flowing out of the flow inlets 460 (or the flow inlets 560) can reach the lowest installation surface 500B of the electronic device 500, thereby avoiding fluid waste. Therefore, costs are reduced and cooling efficiency is improved.

In addition, since the cross-sectional area of the flow inlets 460 (or the flow inlets 560) at the end that is closer to the electronic device 500 is reduced, the flow rate of the fluid flowing to the electronic device 500 can be increased. Therefore, cooling efficiency is improved. Moreover, this design can guide fluid flow to the lowest installation surface 500B of the electronic device 500. In some embodiments, the flow inlets 460 (or the flow inlets 560) may be equipped with a flow guidance structure 600. The flow guidance structure 600 is used to further guide the fluid to the lowest installation surface 500B of the electronic device 500.

In summary, some embodiments of the present disclosure provide an immersion cooling tank and an immersion cooling system including the same, to use a fluid to cool a plurality of electronic devices. The immersion cooling tank includes a casing and a piping assembly. The piping assembly includes a fluid entrance, an inflow main pipe, an inflow branch pipe, and a plurality of flow inlets allowing fluid to flow into the immersion cooling tank. In addition, the piping assembly includes a flow outlet and a fluid exit allowing fluid to flow out of the immersion cooling tank.

Through the design of the size of the flow inlets, the fluid in different flow inlets may have substantially the same amount of flow, flow rate, etc. In addition, since the cross-sectional area of the flow inlets at the end that is closer to the electronic device is reduced, the flow rate of the fluid flowing to the electronic device can be increased. Therefore, cooling efficiency is improved.

In some embodiments, the minimum distance between the lowest installation surface of the electronic device and the flow inlets is between 1 mm and 30 mm, so almost all the fluid flowing out of the flow inlets can reach the lowest installation surface of the electronic device, thereby avoiding fluid waste. Therefore, costs are reduced and cooling efficiency is improved. Moreover, the immersion cooling tank may further include a ring-shaped divider element. The ring-shaped divider element can effectively segregate fluids of different temperatures, guide the fluid to flow in a desired flow direction, and enhance fluid circulation within the immersion cooling tank, thereby improving cooling efficiency.

The foregoing outlines features of several embodiments, so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced in the following description. Those skilled in the art should also realize that such equivalent constructions do not depart from the spirit and scope of the present disclosure, and that they may make various changes, substitutions, and alterations in the following description without departing from the spirit and scope of the present disclosure.

What is claimed is:

1. An immersion cooling tank, comprising:
a casing comprising a positioning element defining a lowest installation surface of an electronic device; and
a piping assembly comprising an inflow branch pipe and a plurality of flow inlets, wherein the flow inlets correspond to the lowest installation surface of the electronic device, the flow inlets are provided on the inflow branch pipe, and size of each of the flow inlets is 1/4.5 to 1/6.5 of size of the inflow branch pipe.

2. The immersion cooling tank as claimed in claim 1, wherein a minimum distance between the lowest installation surface and corresponding one of the flow inlets is between 1 mm and 30 mm.

3. The immersion cooling tank as claimed in claim 1, further comprising:
a fluid entrance; and
an inflow main pipe in fluid communication with the fluid entrance,
wherein the inflow branch pipe is in fluid communication with the inflow main pipe, and the size of the inflow branch pipe is different from size of the inflow main pipe.

4. The immersion cooling tank as claimed in claim 3, wherein the size of inflow branch pipe is less than the size of the inflow main pipe.

5. The immersion cooling tank as claimed in claim 3, wherein the piping assembly further comprises:
a fluid exit;
an outlet pipe in fluid communication with the fluid exit; and
a flow outlet in fluid communication with the outlet pipe,
wherein the fluid exit is located over the fluid entrance.

6. The immersion cooling tank as claimed in claim 5, wherein the size of each of the flow inlets is less than size of the flow outlet.

7. The immersion cooling tank as claimed in claim 5, wherein size of the outlet pipe is equal to size of the flow outlet.

8. The immersion cooling tank as claimed in claim 5, wherein a fluid enters the immersion cooling tank through the fluid entrance, sequentially flows through the inflow main pipe, the inflow branch pipe, and the flow inlets to cool the electronic device.

9. The immersion cooling tank as claimed in claim 8, wherein after heat generated by the electronic device is absorbed by the fluid, the fluid sequentially flows through the flow outlet and the outlet pipe and exits the immersion cooling tank through the fluid exit.

10. The immersion cooling tank as claimed in claim 1, wherein the electronic device corresponds to two rows of flow inlets.

11. The immersion cooling tank as claimed in claim 1, further comprising a ring-shaped divider element disposed on an inner wall surface of the casing.

12. The immersion cooling tank as claimed in claim 11, further comprising a base provided below the ring-shaped divider element.

13. An immersion cooling tank, comprising:
a casing; and
a piping assembly comprising:
a fluid entrance provided on the casing, wherein a fluid enters the casing through the fluid entrance;
a fluid exit provided on the casing, wherein the fluid exits the casing through the fluid exit; and
a ring-shaped divider element,
wherein the ring-shaped divider element is disposed on an inner wall surface of the casing, the ring-shaped divider element protrudes from the inner wall surface of the casing, and the ring-shaped divider element is located between the fluid entrance and the fluid exit, so an interior of the casing is divided into a first zone and a second zone located over the first zone.

14. The immersion cooling tank as claimed in claim 13, wherein temperature of the fluid in the first zone is different from temperature of the fluid in the second zone.

15. The immersion cooling tank as claimed in claim 14, wherein the temperature of the fluid in the first zone is less than the temperature of the fluid in the second zone.

16. The immersion cooling tank as claimed in claim 13, further comprising a baffle, wherein the ring-shaped divider element surrounds the baffle.

17. The immersion cooling tank as claimed in claim 13, the ring-shaped divider element and the casing are in a close fit.

18. The immersion cooling tank as claimed in claim 13, wherein the first zone is area surrounded by the ring-shaped divider element.

19. The immersion cooling tank as claimed in claim 13, wherein the second zone is area located over a topmost surface of the ring-shaped divider element.

20. An immersion cooling system, comprising:
the immersion cooling tank as claimed in claim 1;
a heat exchanger; and
a pump,
wherein a fluid entering and exiting the immersion cooling tank is extracted to the heat exchanger by the pump.
